(19) United States
(12) Patent Application Publication
(10) Pub. No.: US 2007/0217160 A1
(43) Pub. Date: Sep. 20, 2007

(54) Memory Module Including a Cooling Element, Method for Producing the Memory Module Including a Cooling Element, and Data Processing Device Comprising a Memory Module Including a Cooling Element

(75) Inventors: Anton Legen, Munchen (DE); Lutz Morgenroth, Munchen (DE); Klaus Neumaier, Wurmsham (DE); Steve Wood, Munichen (DE)

Correspondence Address: EDELL, SHAPIRO & FINNAN, LLC, 1901 RESEARCH BLVD., SUITE 400, ROCKVILLE, MD, 20850, US

(73) Assignee: Qimonda AG, Munich (DE)

(21) Appl. No.: 11/687,677

(22) Filed: Mar. 19, 2007

(30) Foreign Application Priority Data
Mar. 17, 2006 (DE) 102006012446.4

(51) Int. Cl. H05K 7/20

(52) U.S. Cl. 361/704; 257/706; 360/97.02

(57) ABSTRACT

A memory module includes a cooling element with a board. The board includes a surface on which at least one first electronic component and at least one second electronic component are arranged, a cooling element that is arranged on the surface of the board and includes first and second sections extending in a first direction. At least one stabilizing element that extends in the first direction is arranged at first and second ends of the first section of the cooling element. A surface of the first section of the cooling element is at a first distance from the surface of the board and a surface of the second section of the cooling element is at a second distance from the surface of the board, the first distance being different from the second distance.

### CROSS REFERENCE TO RELATED APPLICATIONS

This application claims priority under 35 U.S.C. §119 to Application No. DE 102006012446.4 filed on Mar. 17, 2006, entitled “Memory Module Having a Cooling Means, Method for Producing the Memory Module Having a Cooling Means, and Data Processing Device Comprising a Memory Module Having a Cooling Means,” the entire contents of which are hereby incorporated by reference.

### BACKGROUND

Data processing devices typically include a plurality or multiplicity of electronic components which generate heat. Overheating of the electronic components may result in a malfunction or in permanent damage to the components, which impairs their functionality.

In order to avoid overheating of electronic components, different mechanisms for cooling the electronic components are used. The cooling mechanisms may comprise, for example, a fan which is provided in a housing of a data processing device and generates a defined air flow for cooling the electronic components.

The data processing devices comprise, in particular, memory modules, for instance DIMMs (dual inline memory modules), for storing data. The memory modules typically comprise a board on which memory chips, for instance DRAM memory chips or SDRAM memory chips, are arranged. Further electronic components which comprise PLL (phase locked loop) circuits or registers may also be arranged on the board. In order to improve heat transport from the electronic components, cooling elements which are in thermal contact with one or more of the individual electronic components are arranged on the board. An edge connector which has contact connections and provides a connection to an external electrical component with a suitable socket for transmitting electrical signals is arranged at one end of the board. The external electronic component may be, for example, a computation unit of the data processing device, a connection being provided between the external component and the memory module using a motherboard which has suitable sockets for holding the memory module.

In server data processing devices, in particular, a plurality of the memory modules are arranged beside one another in the corresponding sockets of the motherboard. The sockets are typically arranged in such a manner that the memory modules extend from the motherboard in a perpendicular manner or inclined at an angle.

As the integration density increases, the distance between adjacent memory modules decreases and the air flow between the cooling elements of adjacent memory modules is too low to ensure sufficient cooling of the memory modules.

Therefore, it is desirable to provide a memory module having an improved means for cooling the memory module. It is also desirable to provide a method for producing a memory module having an improved means for cooling the memory module.

### SUMMARY

A memory module including a cooling element is described herein, as well as a method for producing the memory module including a cooling element, and to a data processing device comprising a memory module including a cooling element. An exemplary embodiment of the memory module is in relation to buffered memory modules.

One embodiment of a memory module including a cooling element comprises a board including a surface on which at least one first electronic component and at least one second electronic component are arranged. A cooling element is arranged on the surface of the board and includes a first section with a first end which extends in a first direction and a second end which extends in the first direction, at least one stabilizing element which extends in the first direction respectively being arranged at the first end and at the second end of the first section of the cooling element. The cooling element also includes a second section and a surface which is remote from the surface of the board. This surface of the first section of the cooling element is at a first distance from the surface of the board and this surface of the second section of the cooling element is at a second distance from the surface of the board, the first distance and the second distance being different.

A method for producing a memory module including a cooling element is also described herein. The method comprises providing a memory module comprising a board including a surface on which at least one first electronic component and at least one second electronic component are arranged. The board includes a first end and a second end which each extend along a first direction.

The method also comprises forming a cooling element, which comprises providing a metal sheet including a first end and a second end. The second end of the metal sheet is bent such that a stabilizing element of the cooling element is formed at the second end of the metal sheet. The operation of forming the cooling element also comprises removing end sections at the first end of the metal sheet such that extensions of the first end of the metal sheet, which are at a distance from one another, are formed, bending the extensions of the first end of the metal sheet, which are at a distance from one another, such that stabilizing elements of the cooling element, which are at a distance from one another, are formed at the first end of the first metal sheet, and forming a recess in the metal sheet, the recess forming a second section of the cooling element, and a region of the metal sheet which is not recessed forming a first section of the cooling element.

The method furthermore comprises arranging the cooling element on the surface of the board, the first end of the board being oriented along the first end of the metal sheet and the second end of the board being oriented along the second end of the metal sheet, such that the first section of the cooling element is in thermal contact with a surface of the at least one first electronic component, which is remote from the surface of the board, and such that the second section of the cooling element is in contact with a surface of the at least one second electronic component, which is remote from the first surface of the board.

A data processing device is also described herein comprising a printed circuit board including a control unit which is arranged on the latter and at least one socket for receiving a memory module. The data processing device furthermore comprises a memory module including a cooling element according to one embodiment, the memory module including an edge connector which is arranged at the second end of the board, and the memory module being coupled to the control unit using the edge connector and the socket.

The above and still further features and advantages of the present invention will become apparent upon consideration of the following detailed description of specific embodiments thereof, particularly when taken in conjunction with the accompanying drawings wherein like reference numerals in the various figures are utilized to designate like components.

### BRIEF DESCRIPTION OF THE DRAWINGS

FIG. 1 diagrammatically shows a plan view of a memory module.

FIG. 2 diagrammatically shows a cross-sectional view of the memory module illustrated in FIG. 1.

FIG. 3 diagrammatically shows a cross-sectional view of the memory module which is illustrated in FIG. 2 and in which a cooling element and a further cooling element are additionally arranged on surfaces of the memory module.

FIG. 4 diagrammatically shows a cross-sectional view, along the sectional direction BB′ illustrated in FIG. 1, of the memory module which is illustrated in FIG. 1 and in which a cooling element is additionally arranged on the surface of the board and a further cooling element is additionally arranged on the further surface of the board.

FIG. 5 diagrammatically shows a perspective view of the cooling elements illustrated in FIG. 3 and FIG. 4.

FIG. 6 shows a flowchart of a method for producing a memory module including a cooling element.

FIG. 7 shows a data processing device with a memory module including a cooling element.

### DETAILED DESCRIPTION

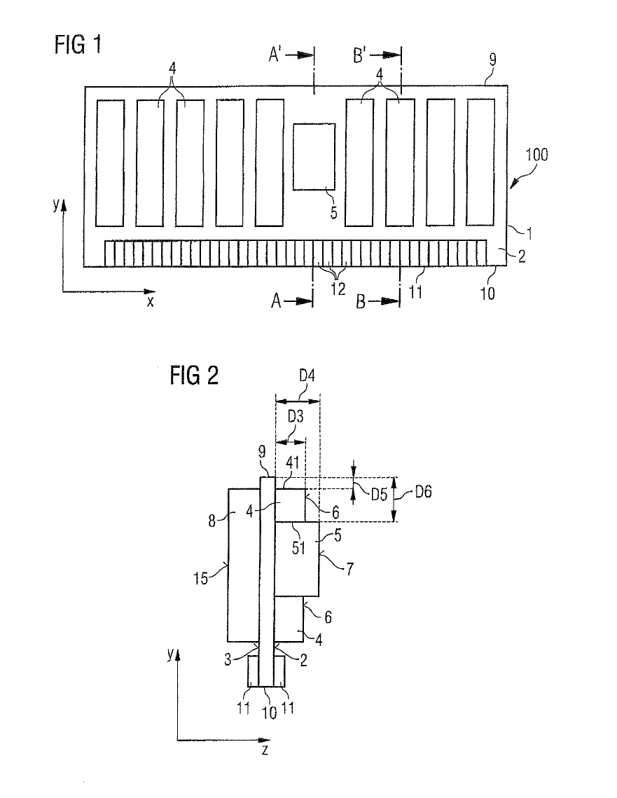

FIG. 1 diagrammatically shows a plan view of a memory module 100. The memory module 100 comprises a board 1 including a surface 2 disposed in a plane defined by the first direction X, which is illustrated in FIG. 1, and by the second direction Y, which is illustrated in FIG. 1. The board 1 also includes a first end 9 and a second end 10. The first end 9 and the second end 10 of the board 1 extend along the first direction X. At least one first electronic component 4 and at least one second electronic component 5 are arranged on the surface 2 of the board 1. The first electronic component 4 is preferably a component for storing data, for instance a dynamic random access memory (DRAM) or a synchronous dynamic random access memory (SDRAM). FIG. 1 illustrates nine first electronic components 4 which are arranged in a row along the first direction X. However, another number of first electronic components 4, which are arranged in a plurality of rows, may also be arranged on the surface 2 of the board. For example, eighteen first electronic components 4, which are arranged in two rows running in the first direction X, or twenty seven first electronic components 4, which are arranged in three rows running in the first direction X, or else thirty six first components 4, which are arranged in four rows running in the first direction X, may also be provided. The second electronic component 5 preferably comprises a phase locked loop (PLL) circuit or a register component. An edge connector 11 including contact connections 12 is arranged at the second end 10 of the board 1. The contact connections 12 are connected to the first electronic components 4 and/or to the second electronic components 5 by electrically conductive structures (not shown in FIG. 1) which are arranged on the board 1. The edge connector 11 can be used to provide a connection for transmitting electrical signals between the memory module 100 and an external electronic component (not shown in FIG. 1) which has a corresponding socket for receiving the memory module 100. The memory module 100 is preferably in the form of a buffered dual inline memory module (DIMM).

FIG. 2 diagrammatically shows a cross-sectional view, along the sectional line AA′ illustrated in FIG. 1, of the memory module 100 illustrated in FIG. 1. A surface 6 of the at least one first electronic component 4, which is remote from the surface 2 of the board 1, is at a distance D3 from the surface 2 of the board 1, which distance is measured along a third direction Z. A surface 7 of the at least one second electronic component 5, which is remote from the surface 2 of the board 1, is at a distance D4 from the surface 2 of the board, which distance is measured along the third direction Z, the distance D3 and the distance D4 being different.

In the embodiment of the memory module 100 illustrated in FIG. 2, the distance D4 is greater than the distance D3. However, the distance D4 may also be less than the distance D3.

One end 41 of the first component 4 is at a distance D5 from the first end 9 of the board 1, which distance is measured along the second direction Y. One end 51 of the second component 5 is at a distance D6 from the first end 9 of the board 1, which distance is measured along the second direction Y. The distance D5 and the distance D6 are preferably different.

The board 1 includes a further surface 3 on which at least one third electronic component 8 is arranged. The third component 8 has a surface 15 which is remote from the further surface 3 of the board 1. The at least one third electronic component 8 may be, for example, a component for storing data, for instance a dynamic random access memory (DRAM) or a synchronous dynamic random access memory (SDRAM). At least one fourth component (not shown in FIG. 2) may also be arranged on the further surface 3 of the board 1, the fourth component (not shown in FIG. 2) being able to comprise a PLL circuit or a register.

Edge connectors 11 are respectively arranged at the second end 10 of the board 1 on the surface 2 of the board 1 and on the further surface 3 of the board 1.

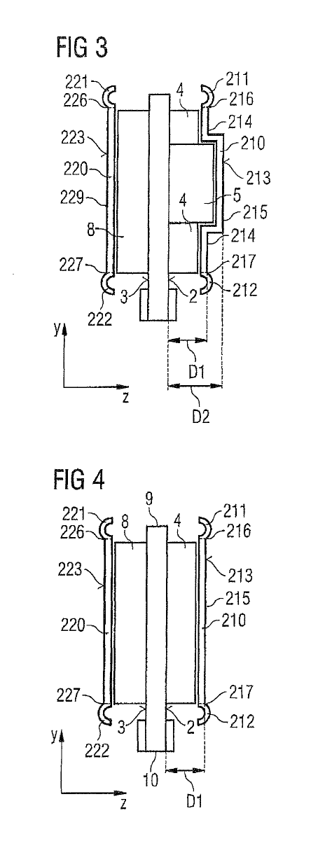

FIG. 3 diagrammatically shows a cross-sectional view of the memory module 100 which is illustrated in FIG. 2 and in which a cooling element 210 is additionally arranged on the surface 2 of the board 1 and a further cooling element 220 is additionally arranged on the further surface 3 of the board 1. The cooling element 210 and the further cooling element 220 preferably comprise a material having high thermal conductivity.

The cooling element 210 has a surface 213 which is remote from the surface 2 of the board 1. In addition, the cooling element 210 has a first section 214 including a first end 216 and a second end 217, each of which extend along the first direction X.

At least one stabilizing element 211, 212 which extends along the first direction X is respectively provided at the first end 216 and at the second end 217 of the first section 214 of the cooling element 210. The stabilizing elements 211, 212 may each be in the form of profiled sections of the cooling element 210, the sections having a longitudinal contour. The stabilizing elements 211, 212 may have a semicircular profile, as seen on the plane defined by the second direction Y and by the third direction Z, or an arcuate profile. However, the stabilizing elements 211, 212 may also be in the form of an extension of the cooling element 210 with an angled or L-shaped profile.

The first section 214 of the cooling element 210 is arranged on the at least one first electronic component 4 and is in thermal contact with the surface 6 of the first electronic component 4. The cooling element 210 also has a second section 215 which is arranged on the second component 5 and is in thermal contact with the surface 7 of the second electronic component 5.

A surface of the first section 214 of the cooling element 211, which is remote from the surface 2 of the board 1, is at a distance D1 from the surface 2 of the board 1, and a surface of the second section 215 of the cooling element 210, which is remote from the surface 2 of the board 1, is at a distance D2 from the surface 2 of the board 1, the distance D1 and the distance D2 being different.

In the present embodiment, the distance D2 is greater than the distance D1. However, the distance D2 may also be less than the distance D1.

The first section 214 and the second section 215 of the cooling element 210 are preferably formed using a pressing method in which a recess is formed in a metal sheet. The recessed region of the metal sheet then constitutes the second section 215 of the cooling element 210 and that region of the metal sheet which is not recessed constitutes the first section 214 of the cooling element 210. The second section 215 of the cooling element 210 is thus surrounded by the first section 214 of the cooling element 210.

The cooling element 210 may also have a plurality of sections whose surfaces which are remote from the surface 2 of the board 1 are at different distances from the surface 2 of the board 1, the distances each being matched to the dimensions of electronic components arranged on the surface 2 of the board 1.

This configuration of the cooling element including at least two sections whose surfaces which are remote from the surface 2 of the board 1 are at different distances from the surface 2 of the board 1 enables, in the event of a plurality of the memory modules 100 being arranged adjacent to one another in a data processing device, an improved air flow between the adjacent memory modules 100 and thus increased heat dissipation from the memory modules. This makes it possible to avoid overheating of the memory modules 100.

The further cooling element 220 includes a surface 223 which is remote from the further surface 3 of the board 1. In addition, the further cooling element 220 has a section 229 having a first end 226 and a second end 227 which each extend along the first direction X. Stabilizing elements 221, 222 which each extend along the first direction X are provided at the first end 226 and at the second end 227 of the section 229 of the further cooling element 220. The stabilizing elements 221, 222 may each be in the form of profiled sections of the further cooling element 220, the sections having a longitudinal contour. The stabilizing elements 221, 222 may have a semicircular profile on the plane defined by the second direction Y and by the third direction Z, or an arcuate profile. However, the stabilizing elements 221, 222 may also be in the form of an extension of the further cooling element 220 with an angled or L-shaped profile.

The section 229 of the further cooling element 220 is arranged such that it is in direct thermal contact with the at least one third electronic component 8.

FIG. 4 diagrammatically shows a cross-sectional view, along the sectional direction BB′, of the memory module 100 which is illustrated in FIG. 1 and in which the cooling element 210 is additionally arranged on the surface 2 of the board 1 and the further cooling element 220 is additionally arranged on the further surface 3 of the board 1. In contrast to the cross section shown in FIG. 3, the cooling element 210 has, in this cross section, only the second section 215 whose surface 213 which is remote from the surface 2 of the board 1 is at the distance D1.

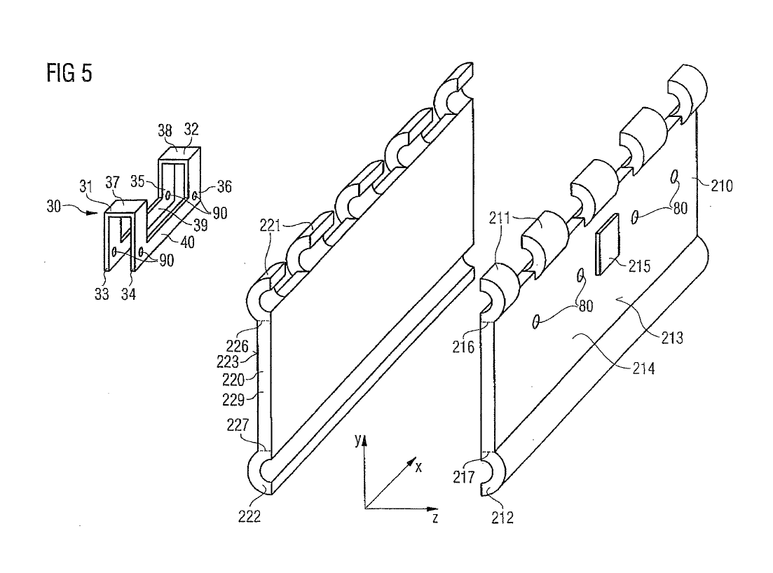

FIG. 5 diagrammatically shows a perspective view of the arrangement of the cooling element 210 illustrated in FIG. 3 and FIG. 4 and of the further cooling element 220, the memory module 100 which is illustrated in FIG. 3 and FIG. 4 and is arranged between the cooling element 210 and the further cooling element 220 not being illustrated for reasons of clarity. In addition, the cooling element 210 and the further cooling element 220 are illustrated at a greater distance from one another for reasons of clarity.

The cooling element 210 includes a plurality of the stabilizing elements 211 which are arranged at a distance from one another along the first direction X, and the further cooling element 220 has a plurality of the stabilizing elements 221 which are arranged at a distance from one another along the first direction X, each of the plurality of stabilizing elements 211 of the cooling element 210 being opposite a respective one of the plurality of stabilizing elements 221 of the further cooling element 220.

A fastening element 30 which may be in the form of a clip and is intended to fasten the cooling element 210 and the further cooling element 220 to the board 1 (not shown in FIG. 5) is also illustrated. The fastening element 30 has a first bracket 31 and a second bracket 32 each having a first end 33, 35 and a second end 34, 36 as well as a central section 37, 38. The first end 33 of the first bracket 31 and the first end 35 of the second bracket 34 are connected to one another by a first connecting piece 39. The second end 34 of the first bracket 31 and the second end 36 of the second bracket 32 are connected to one another by a second connecting piece 40.

The cooling element 210 and the further cooling element 220 each include latching-in apparatuses 80 (not shown for the further cooling element 220) which are arranged on the respective surfaces 213, 223 and are in the form of bumps. The latching-in apparatuses 80 are used to fix the fastening element 30. To this end, cutouts 90 which latch into the respective latching-in apparatuses 80 are respectively provided at the respective first ends 33, 35 and second ends 34, 36 of the first bracket 31 and of the second bracket 32 of the fastening element 30.

In order to fasten the cooling element 210 and the further cooling element 220 to the memory module 100 (not shown in FIG. 5), respective central sections 37, 38 of the first bracket 31 and of the second bracket 32 of the fastening element 30 are arranged on respective sections of the first end 9 of the board 1 (not shown in FIG. 5) which are arranged between adjacent stabilizing elements 211 of the cooling element 210 and between adjacent stabilizing elements 221 of the further cooling element 220. The respective first ends 33, 35 of the first bracket 31 and of the second bracket 32 of the fastening element 30 and the first connecting piece 39 touch the surface 223 (not shown in FIG. 5) of the further cooling element 220. The respective second ends 34, 36 of the first bracket 31 and of the second bracket 32 of the fastening element 30 and the second connecting piece 40 touch that surface 213 of the cooling element 210 which is remote from the surface 2 of the board 1. The fastening element 30 exerts forces which push the cooling element 210 and the further cooling element 220 in the direction of the board 1 in each case. As a result, good thermal contact is achieved between the cooling element 210 and the first electronic component 4 and the second electronic component 5 and good thermal contact is achieved between the further cooling element 220 and the third electronic component 8. The stabilizing elements 211, 212 reduce twisting of the cooling element 210 and the stabilizing elements 221, 222 of the further cooling element 220 reduce twisting of the further cooling element 220. In particular, reducing twisting of the cooling element 210 and of the further cooling element 220 increases the contact area between the individual electronic components and the cooling element 210 or the further cooling element 220.

As shown in FIG. 5, the second section 215 of the cooling element 210 adjoins the first section 214 of the cooling element 210 and is surrounded by the latter.

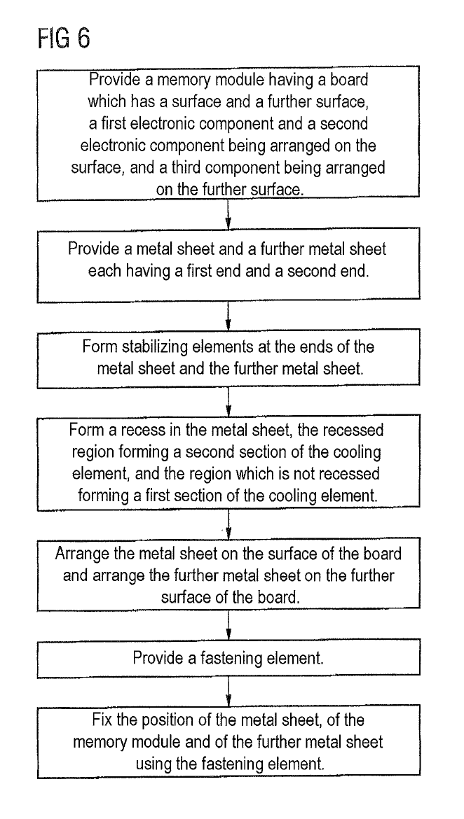

FIG. 6 shows a flowchart for producing a memory module 100 including a cooling element according to one embodiment. The method comprises providing a memory module 100 including a board 1 which includes a surface 2 and a further surface 3 which is remote from the surface 2. The board 1 includes a first end 9 and a second end 10 which each extend in a first direction X. At least one first electronic component 4 and at least one second electronic component 5 are arranged on the surface 2 of the board. At least one third electronic component 8 is arranged on the further surface 3 of the board 1.

The method also comprises forming a cooling element 210 and a further cooling element 220. The operation of forming the cooling element 210 and the further cooling element 220 comprises providing a metal sheet and providing a further metal sheet each having a first end and a second end. Latching-in apparatuses 80, for example bumps, for latching in a fastening element 30 are formed on respective surfaces of the metal sheet and of the further metal sheet. The second ends of the metal sheet and of the further metal sheet are bent such that longitudinally bent sections of the respective metal sheet are formed and each form the stabilizing element 212 of the cooling element 210 and the stabilizing element 222 of the further cooling element 220. End sections are removed at the first ends of the metal sheet and of the further metal sheet, for example by a stamping process, such that extensions of the metal sheet and of the further metal sheet, which are at a distance from one another, are formed. The extensions of the metal sheet and of the further metal sheet, which are at a distance from one another, are bent such that longitudinally bent sections of the respective metal sheet, which are at a distance from one another and each form stabilizing elements 211 of the cooling element 210 and stabilizing elements 221 of the further cooling element 220, are formed.

A recess is also formed in the metal sheet, the recessed region forming a second section 215 of the cooling element 210, and that region of the metal sheet which is not recessed forming a first section 214 of the cooling element 210.

The metal sheet processed according to the above method constitutes the cooling element 210, and the further metal sheet processed according to the above method constitutes the further cooling element 220.

The cooling element 210 is arranged on the surface 2 of the board 1 such that the first section 214 of the cooling element 210 is in thermal contact with a surface 6 of the at least one first electronic component 4, which is remote from the surface 2 of the board 1, and such that the second section 215 of the cooling element 210 is in contact with a surface 7 of the at least one second electronic component 5, which is remote from the surface 2 of the board 1.

The further cooling element 220 is arranged on the further surface 3 of the board 1 such that the further cooling element 220 is in contact with a surface 15 of the at least one third electronic component 8, which is remote from the further surface 3 of the board 1.

The method furthermore comprises providing a fastening element 30. The fastening element 30 may have a first bracket 31 and a second bracket 32 each having a first end 33, 35 and a second end 34, 36 as well as a central section 37, 38. The first end 33 of the first bracket 31 and the first end 35 of the second bracket 34 are connected to one another by means of a first connecting piece 39. The second end 34 of the first bracket 31 and the second end 36 of the second bracket 32 are connected to one another by means of a second connecting piece 40. Cutouts 90 are respectively provided at the respective first ends 33, 35 and second ends 34, 36 of the first bracket 31 and of the second bracket 32 of the fastening element 30.

The position of the cooling element 210, of the memory module 100 and of the further cooling element 220 is then fixed using the fastening element 30. Thus, the fastening element secures the cooling elements with respect to the board at a fixed and defined position with respect to the board.

To this end, respective central sections 37, 38 of the first bracket 31 and of the second bracket 32 of the fastening element 30 are arranged on respective sections of the first end 9 of the board 1 which are arranged between adjacent stabilizing elements 211, 221 of the cooling element 210 and of the further cooling element 220. The respective first ends 33, 35 of the first bracket 31 and of the second bracket 32 of the fastening element 30 and the first connecting piece 39 touch the surface 223 of the further cooling element 220. The respective second ends 34, 36 of the first bracket 31 and of the second bracket 32 of the fastening element 30 and the second connecting piece 40 touch a surface 213 of the cooling element 210, which is remote from the surface 2 of the board 1. The latching-in apparatuses 80 of the cooling element 210 and of the further cooling element 220 latch into the cutouts 90 of the fastening element 30.

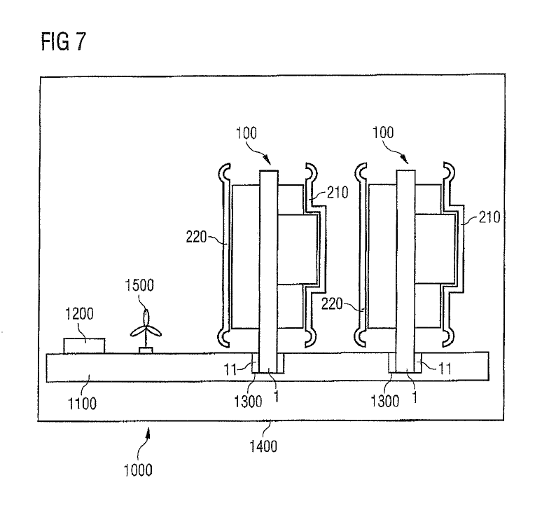

FIG. 7 diagrammatically shows a data processing device 1000 including a plurality of memory modules 100 with cooling elements 210, 220 which are arranged on the surfaces of the board 1 of the respective memory modules 100. The data processing device 1000 comprises a printed circuit board 1100 on which a control unit 1200 and a plurality of sockets 1300 are arranged. Each of the memory modules 100 has an edge contact 11, the contacts each being plugged into corresponding sockets 1300 of the printed circuit board 1100. Conductive conductor tracks (not shown in FIG. 7) which are integrated in the printed circuit board 1100 are used to provide a connection between the control unit and the respective memory modules 100 for the purpose of transmitting data. The data processing device 1000 comprises a housing 1400 and a fan 1500 which is arranged in the latter. The fan 1500 generates a directed air flow such that air flows between the individual memory modules 100 and dissipates heat generated by the memory modules 100. On account of the configuration of the cooling element 210, in which a surface of the cooling element 210 has sections at different distances from a surface of the board 1, the air flow between adjacent memory modules 100 is hindered only slightly. This results in improved heat transport from the memory modules 100.

While the invention has been described in detail and with reference to specific embodiments thereof, it will be apparent to one skilled in the art that various changes and modifications can be made therein without departing from the spirit and scope thereof. Accordingly, it is intended that the present invention covers the modifications and variations of this invention provided they come within the scope of the appended claims and their equivalents.

What is claimed is:

1. A memory module comprising:
a board including a first surface upon which at least one first electronic component and at least one second electronic component are arranged; and
a cooling element arranged on the board proximate the first and second components, the cooling element comprising a first section and a second section, the first section including a first end and a second end that extend in a first direction, at least one stabilizing element that extends in the first direction and is respectively disposed at the first end and/or at the second end of the first section of the cooling element, wherein the first and second sections include surfaces that face away and are remote from the first surface of the board, the surface of the first section being at a first distance from the first surface of the board and the surface of the second section being at a second distance from the first surface of the board, and the first distance is different from the second distance.

2. The memory module of claim 1, wherein the board includes a second surface that opposes the surface of the board, and the memory module further comprises at least one third electronic component arranged upon the second surface of the board, and a further cooling element that comprises a section arranged proximate the at least one third electronic component, wherein the section of the further cooling element includes a first end and a second end that extend in the first direction, and at least one stabilizing element arranged at the first end and/or at the second end of the third section of the further cooling element.

3. The memory module of claim 1, wherein the at least one first component includes a surface that faces away and is at a third distance from the first surface of the board, the at least one second component includes a surface that faces away and is at a fourth distance from the first surface of the board, and the third distance is different from the fourth distance.

4. The memory module of claim 3, wherein the first section of the cooling element is in thermal contact with the first surface of the at least one first electronic component and the second section of the cooling element is in thermal contact with the surface of the at least one second electronic component.

5. The memory module of claim 1, wherein the second section of the cooling element is defined by a recess in the first section of the cooling element.

6. The memory module of claim 1, wherein the at least one stabilizing element includes a profiled longitudinal structure.

7. The memory module of claim 2, wherein at least one fastening element holds the first and second sections of the cooling element together with the section of the further cooling element in a fixed and defined position with respect to the board.

8. The memory module of claim 7, wherein at least one the fastening element comprises a clip that secures the cooling element and the further cooling element together with respect to the board.

9. The memory module of claim 7, wherein each of the cooling element and the further cooling element includes latching structure arranged to engage with corresponding latching structure of the at least one fastening element.

10. The memory module of claim 9, wherein the at least one fastening element includes at least one cutout that latches with corresponding latching structure of the cooling element and further cooling element.

11. The memory module of claim 9, wherein the latching structure of each of the cooling element and the further cooling element comprises at least one bump disposed on a surface of each of the cooling element and the further cooling element.

12. The memory module of claim 9, wherein the latching structure of the cooling element is arranged on a surface of the cooling element that opposes the first surface of the board, and the latching structure of the further cooling element is arranged on a surface of the further cooling element that opposes the second surface of the board.

13. The memory module of claim 2, wherein a plurality of stabilizing elements are disposed at the first end of the first section of the cooling element and at spaced distances from each other along the first direction, a plurality of stabilizing elements are disposed at the first end of the section of the further cooling element at spaced distances from each other along the first direction, the first ends of the cooling element and the further cooling element corresponding to each other, and each of the plurality of stabilizing elements at the first end of the first section of the cooling element oppose a corresponding one of the plurality of stabilizing elements at the first end of the section of the further cooling element.

14. The memory module of claim 2, wherein each of the at least one first electronic component and the at least one third electronic component comprises at least one of a dynamic random access memory (DRAM) and a synchronous dynamic random access memory (SDRAM).

15. The memory module of claim 1, wherein the at least one second electronic component comprises at least one of phase locked loop (PLL) circuit and a register.

16. A method for producing a memory module with a cooling element, the method comprising:
providing a memory module comprising a board including a first surface on which at least one first electronic component and at least one second electronic component are arranged, wherein the board further includes a first end and a second end which extend in a first direction;
forming a cooling element by:
providing a metal sheet including a first section with a first end and a second end;
bending the second end of the metal sheet to form a stabilizing element at the second end of the metal sheet;
removing end sections at the first end of the metal sheet to form extensions at the first end of the metal sheet that are spaced from each other;
bending the extensions at the first end of the metal sheet to form stabilizing elements at the first end of the first metal sheet that are spaced apart from each other; and
forming a recess in the first section of the metal sheet so as to define a second section that is surrounded by the first section; and
arranging the cooling element on the surface of the board such that the first end of the metal sheet is oriented along the first end of the board, the second end of the metal sheet is oriented along the second end of the board, the first section of the cooling element is in thermal contact with a surface of the at least one first electronic component that is remote from the first surface of the board, and the second section of the cooling element is in thermal contact with a surface of the at least one second electronic component that faces away and is remote from the first surface of the board.

17. The method of claim 16, wherein the board includes a second surface that opposes the first surface of the board, and at least one third electronic component is arranged on the second surface of the board, the method further comprising:
forming a further cooling element by:
providing a further metal sheet including a first end and a second end;
bending the second end of the further metal sheet to form a stabilizing element at the second end of the further metal sheet;
removing end sections at the first end of the further metal sheet to form extensions at the first end of the further metal sheet that are distanced from each other; and
bending the extensions at the first end of the further metal sheet to form stabilizing elements that are distanced from each other at the first end of the further metal sheet; and
arranging the further cooling element on the second surface of the board such that the further cooling element is in thermal contact with a surface of the at least one third electronic component that faces away and is remote from the second surface of the board.

18. The method of claim 17, further comprising:
providing at least one fastening element;
securing the cooling element and the further cooling element in fixed positions with respect to the board using the at least one fastening element.

19. The method of claim 18, wherein at least one latching structure is formed on a surface of the cooling element, at least one latching structure is formed on a surface of the further cooling element, and the at least one fastening element includes at least one cutout that engages and latches with the at least one latching structure of each of the cooling element and further cooling element during securing of the cooling element and the further cooling element in fixed positions with respect to the board using the at least one fastening element.

20. The method of claim 16, wherein each of the at least one first electronic component and the at least one third electronic component comprises at least one of a dynamic random access memory (DRAM) and a synchronous dynamic random access memory (SDRAM).

21. The method of claim 16, wherein the at least one second electronic component comprises at least one of a phase locked loop (PLL) circuit and a register.

22. The method of claim 16, wherein the memory module comprises a dual inline memory module (DIMM).

23. A data processing device comprising:
a printed circuit board including a control unit that is arranged on the printed circuit board and at least one socket to hold a memory module; and
a memory module as recited in claim 1 and further comprising an edge connector that is arranged at an end of the board to facilitate connection with the socket of the printed circuit board, wherein the memory module couples to the control unit via a connection between the edge connector and the socket.

24. The data processing device of claim 23, further comprising a housing and a fan arranged on the printed circuit board.
